(19) United States
(12) Patent Application Publication
(10) Pub. No.: US 2012/0120569 A1
(43) Pub. Date: May 17, 2012

(54) BATTERY CASE

(75) Inventor: Moo-Ryong BAEK, Yongin-si (KR)

(73) Assignee: Samsung SDI Co., Ltd., Yongin-si (KR)

(21) Appl. No.: 13/117,505

(22) Filed: May 27, 2011

(30) Foreign Application Priority Data
Nov. 11, 2010 (KR) 10-2010-0112078

(51) Int. Cl. H05K 5/00; H01M 2/10

(52) U.S. Cl. 361/679.01; 429/100

(57) ABSTRACT

A battery case having an anti-reverse insertion locking device is provided. A locking device includes a latch, a first case and a knob. The latch has one end at which a fixing projection is formed and the other end at which an elastic portion is formed. The latch has a first coupling groove formed therein. In the latch, the first coupling groove is asymmetric with respect to a length or width direction thereof. The first case has first and second through-holes formed therein. In the first case, the fixing projection enters/exits the second through-hole. The knob has a first coupling projection formed thereon. In the knob, the first coupling projection is inserted into the first coupling groove by passing through the first through-hole. Accordingly, it is possible to a knob and a latch, which have a directional property, from being in a reserve or wrong direction in a manufacturing process.

### CLAIM PRIORITY

This application claims priority to and the benefit of Korean Patent Application No. 10-2010-0112078, filed on Nov. 11, 2010, in the Korean Intellectual Property Office, the entire content of which is incorporated herein by reference.

### BACKGROUND OF THE INVENTION

1. Field of the Invention

An aspect of the present invention relates to a battery case, and more particularly, to a battery case having a locking device capable of preventing a battery from being inserted in a reserve or wrong direction in a manufacturing process.

2. Description of the Related Art

In general, battery packs used in external portable electronic devices such as personal digital assistants (PDAs) and camcorders are manufactured in an attachable and detachable type due to limitations regarding the capacity of battery cells.

### SUMMARY OF THE INVENTION

Embodiments of the present invention provide a battery case having a locking device capable of preventing a battery from being inserted in the reverse, or wrong direction, in a manufacturing process.

According to an aspect of the present invention, a battery case includes a latch, a first case and a knob.

The latch has one end at which a fixing projection is formed and the other end at which an elastic portion is formed. The latch has a first coupling groove formed therein. In the latch, the first coupling groove is asymmetric with respect to a length or width direction thereof. The first case has first and second through-holes formed therein. In the first case, the fixing projection enters/exits the second through-hole. The knob has a first coupling projection formed of the latch. In the knob, the first coupling projection is inserted into the first coupling groove by passing through the first through-hole.

The first coupling groove may be asymmetric with respect to the length direction of the latch and symmetric with respect to the width direction of the latch. A second coupling projection may be formed on an inner circumferential surface of the first coupling groove, and the cross-sectional shape of the first coupling projection may be formed to accommodate the second coupling projection. The second coupling projection may be formed in the direction of the fixing projection of the latch.

A guide portion that accommodates and guides the latch to move in the length direction of the latch may be formed in the first case.

Rib coupling grooves may be formed at both sides of the first coupling groove of the latch, respectively, and ribs inserted into the rib coupling grooves may be formed at both sides of the first coupling projection of the knob, respectively. A hook fixed to each of the rib coupling grooves may be formed at an end of each of the ribs.

A concave-convex portion may be formed on the other side surface of each of the first coupling grooves of the knob. The concave-convex portion may be formed to be biased to a side with respect to the length direction thereof. The concave-convex portion may be formed to be biased to the direction of the fixing projection.

According to an aspect of the present invention, there is provided a notebook case including the battery case described above.

As described above, in a battery case according to embodiments of the present invention, it is possible to prevent a knob and a latch, which have a directional property, from being in the reverse, or wrong direction, in a manufacturing process.

Also, the failure rate of the battery case can be reduced, so that it is advantageous in terms of economy and time.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a partial perspective view showing an outside of a notebook case according to an embodiment of the present invention.

FIG. 2 is a partial perspective view showing an inside of the notebook case of FIG. 1.

FIG. 3 is a perspective view of a knob according to an embodiment of the present invention.

FIG. 4 is a perspective view showing a bottom of the knob of FIG. 3.

FIG. 5 is a perspective view showing the knob and the notebook case according to an embodiment of the present invention.

FIG. 6 is a perspective view showing a state where the knob of FIG. 5 and notebook case are coupled to each other.

FIG. 7 is a perspective view of a latch according to an embodiment of the present invention.

FIG. 8 is a perspective view showing a state where the latch and the notebook case are coupled to each other.

FIG. 9 is an exploded perspective view showing a state where the notebook case, the latch and the knob are coupled to one another.

FIG. 10 is a bottom perspective view of a knob according to another embodiment of the present invention.

FIG. 11 is a partial perspective view of a latch corresponding to the knob of FIG. 10.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements. When terms that indicate directions, such as top, bottom left and right, are used without special notation, the terms indicate directions represented in the drawings.

Several locking devices are used for the purpose of attaching and detaching battery packs and the like. Such locking devices are formed at a notebook case and a case, of a battery pack, respectively, so that they are fixed to each other.

Meanwhile, a latch for fixing a battery pack to a notebook case, or the like, and a knob for operating the latch are generally used as a locking device. However, the latch is frequently formed to have a constant directional property. In a case where the directional property is neglected and the battery pack is wrongly inserted in the manufacturing process, a product failure occurs, and serious economic and temporal problems follow.

A locking device provided for a battery case according to embodiments of the present invention may be included and used in various other products or devices. However, in this specification, a notebook computer provided with a removable battery pack will be described as an example.

### Embodiment 1

A notebook computer according to an embodiment may be divided into a notebook case, a battery case and a locking device provided to each of the notebook case and the battery case. Hereinafter, components that constitute the notebook computer will be described in detail.

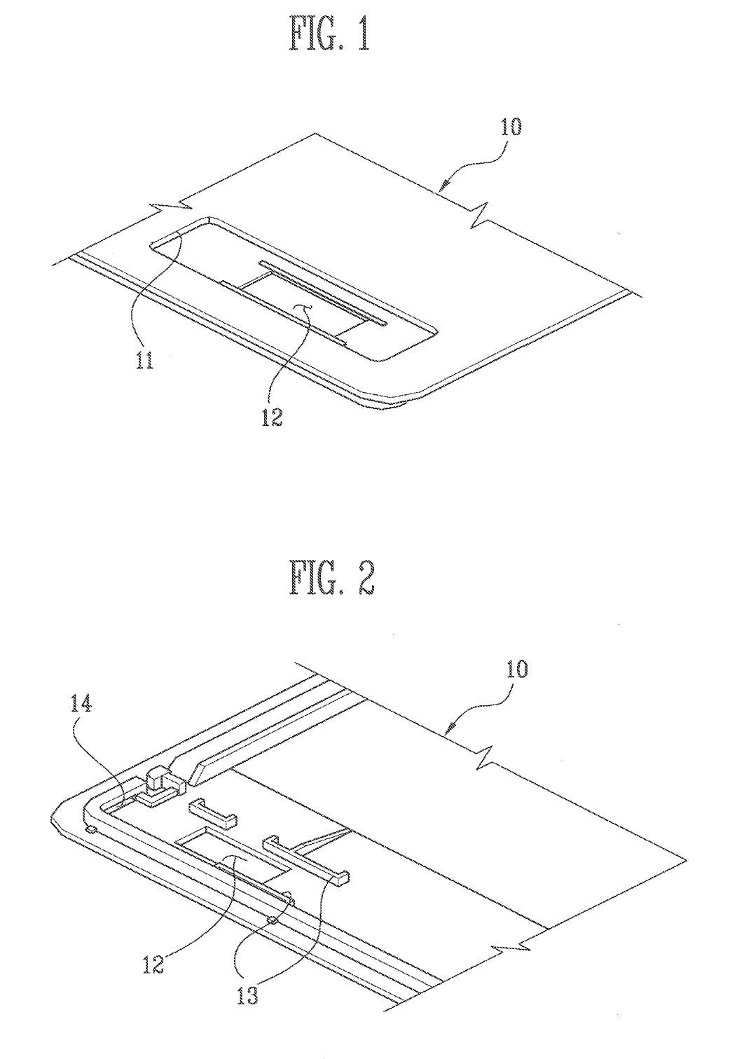

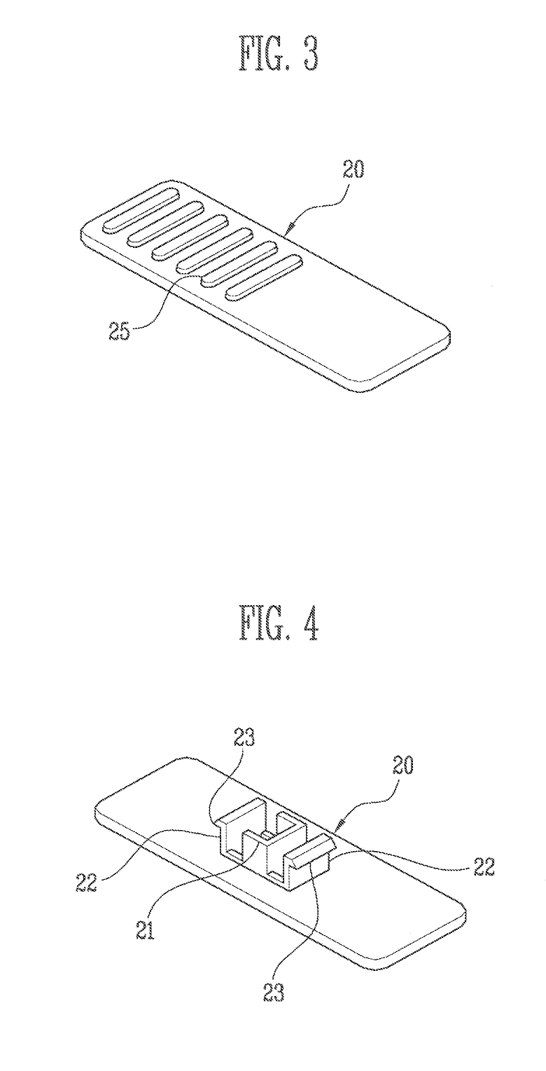

A notebook case 10 will be described with reference to FIGS. 1 and 2. FIG. 1 is a partial perspective view showing an outside of the notebook case 10 according to an embodiment of the present invention. FIG. 2 is a partial perspective view showing an inside of the notebook case 10 of FIG. 1.

As shown in FIG. 1, a first through-hole 12 is formed in the notebook case 10. The first through-hole 12 is formed in the vicinity of a position at which the battery pack (not shown) is to be coupled to the notebook case 10. The first through-hole 12 is formed to have a predetermined length. The guide portion 11 formed to be stepped deeper than surroundings is also formed in the vicinity of the first through-hole 12. Meanwhile, as shown in FIG. 2, a second through-hole 14 is formed at one side of the notebook case 10. The second through-hole 14 is formed at a side in the direction of the battery pack (not shown) with respect to the first through-hole 12.

The functions of the first through-hole 12, the guide portion 11 and the second through-hole 14 will be described later.

A guide wall 13 may be formed along the length direction of the first through-hole 12. The guide wall 13 functions to guide a latch which will be described later to move in a predetermined direction.

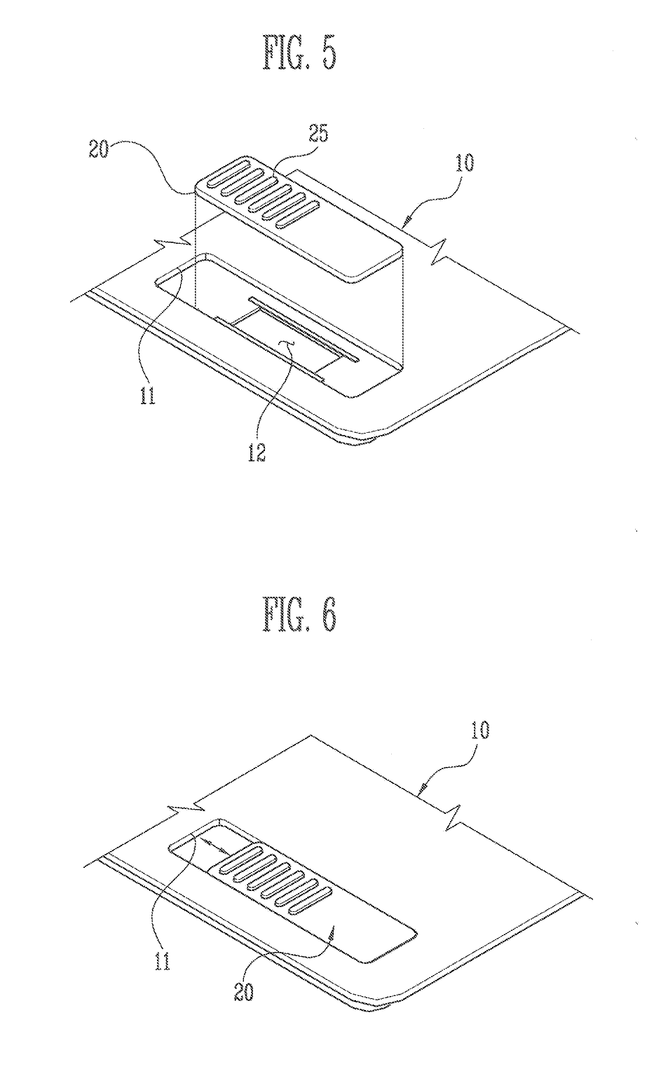

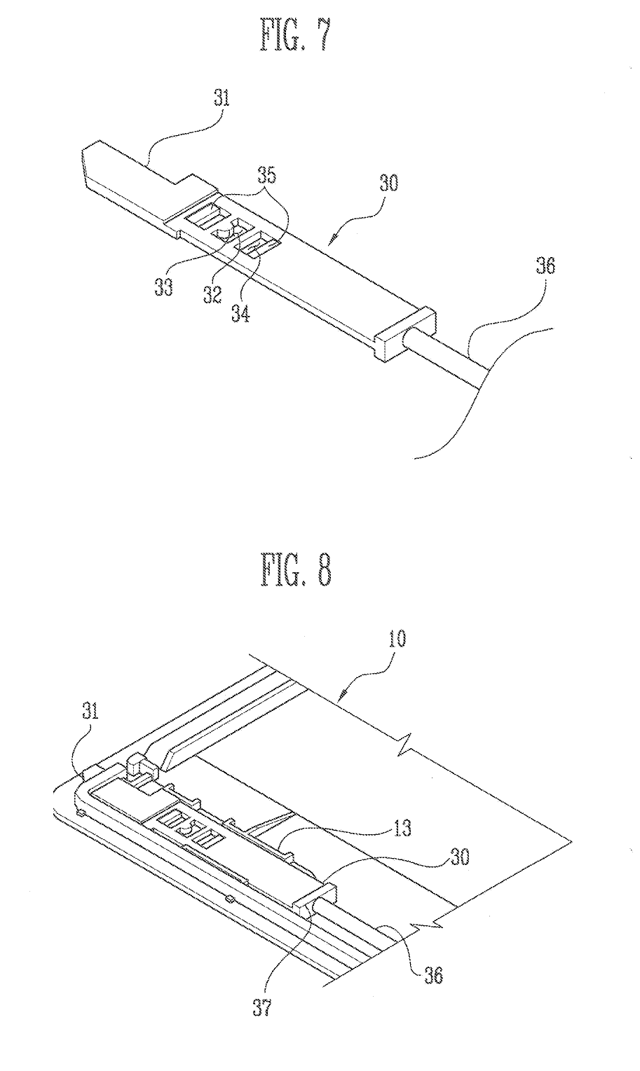

A knob 20 will be described with reference to FIGS. 3 to 6. FIG. 3 is a perspective view of the knob 20 according to an embodiment of the present invention. FIG. 4 is a perspective view showing a bottom of the knob of FIG. 3. FIG. 5 is a perspective view showing the knob 20 and the notebook case 10 according to the embodiment of the present invention. FIG. 6 is a perspective view showing a state where the knob 20 of FIG. 5 and the notebook case are coupled to each other.

As shown in FIG. 3, a concave-convex portion 25 is formed on a top surface of the knob 20. The concave-convex portion 25 functions to increase a frictional force while coming in contact with a user's hand. In a case where a user pushes or pulls the knob 20, as the frictional force is increased by the concave-convex portion 25, the knob 20 can be easily moved without sliding. In this instance, the concave-convex portion 25 may be formed to be biased to any one of the length directions thereof. In order to effectively apply a force, the concave-convex portion 25 may be formed to be biased to the direction of a fixing projection 31 (see FIG. 9) which will be described later.

As shown in FIG. 4, a first coupling projection 21 is formed on a bottom surface of the knob 20. The first coupling projection 21 is formed asymmetric about the length or width direction of the knob 20. In this embodiment, a predetermined accommodation space in the length direction of the knob 20 is formed in the first coupling projection 21, so that the first coupling projection 21 is formed asymmetric.

Protruded ribs 22 may be formed at both sides of the first coupling projection 21 with respect to the length direction of the knob 20, respectively. The ribs 22 are formed in a shape protruded in the same direction, at the same angle, as the first coupling projection 21. Meanwhile, a hook 23 may be formed at an end of each of the ribs 22.

The knob 20 is assembled with the notebook case 10 toward the inside of the guide portion 11. In this instance, the first coupling projection 21 and the ribs 22 in the knob 20 are exposed to the inside, opposite to the outside, of the notebook case 10 through the first through-hole 12. As shown in FIG. 6, the knob 20 is guided and limited so as to travel along the guide portion 11 in the length direction thereof.

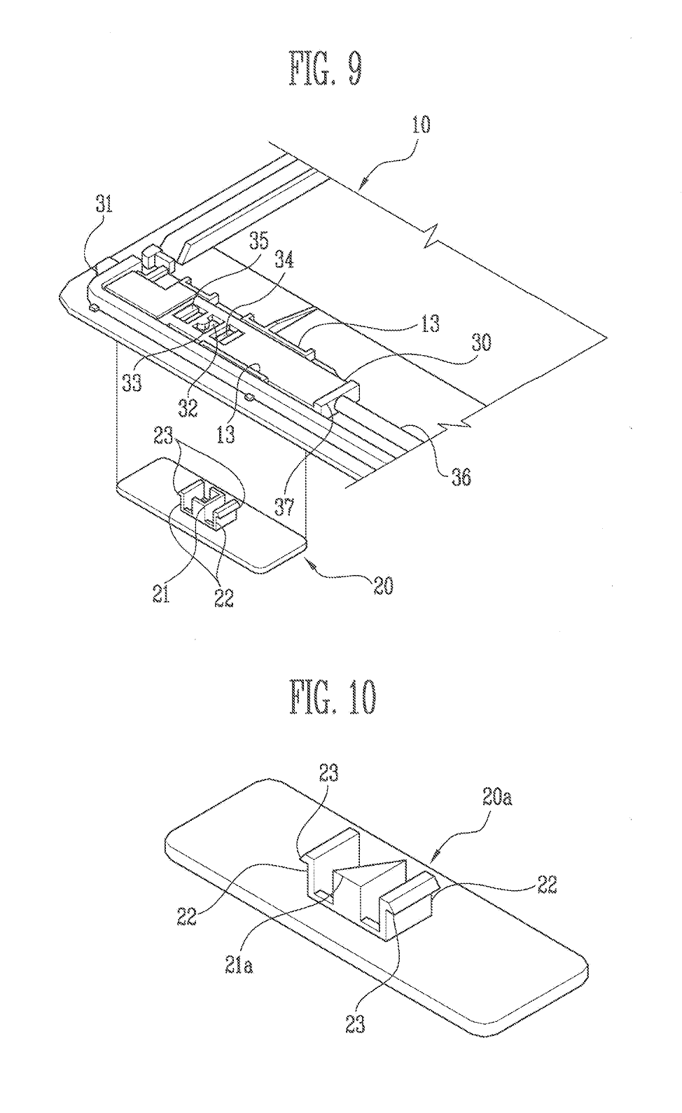

A latch 30 will be described with reference to FIGS. 7 and 8. FIG. 7 is a perspective view of the latch 30 according to the embodiment of the present invention. FIG. 8 is a perspective view showing a state where the latch 30 and the notebook case 10 are coupled to each other.

The latch 30 is formed to have a predetermined length. A fixing projection 31 is formed at one end of the latch 30. A portion of the fixing projection 31 is inserted into the battery case (not shown) so as to fix the battery case (not shown). Since the shape and function of the fixing projection 31 are not significantly different from those of the fixing projections in the related art, a detailed description will be omitted.

A first coupling groove 32 is formed at a central portion of the latch 30. The first coupling groove 32 is formed asymmetric with respect to the length or width direction thereof, so that the asymmetric first coupling projection 21 (see FIG. 4) can be inserted with a small gap into the first coupling groove 32. In this embodiment, a second projection 33 is formed on an inner circumferential surface of the first coupling groove 32, as an example of the asymmetry. Meanwhile, the second projection 33 may be formed to be close to the direction of the fixing projection 31 of the latch 30.

Rib coupling grooves 34 may be formed at both sides of the first coupling groove 32 of the latch 30, respectively. A stepped portion 35 formed to be stepped deeper than its surroundings may be formed at the outside of each of the rib coupling grooves 34. The functions of the rib coupling grooves 34 and the stepped portion 35 will be described later.

An elastic portion 36 is formed at the other side of the fixing projection 31. The elastic portion 36 is provided with an elastic member such as a spring, so that elastic repulsive power can be applied to the movement of the latch 30. Since the configuration of the elastic portion 36 is not significantly different from that of the elastic portion of the related art, a detailed description will be omitted.

As shown in FIG. 8, the latch 30 is assembled to move along the guide wall 13. In this instance, the fixing projection 31 is moved in the state that it is inserted into the second through-hole 14.

A coupling relationship between the knob 20 and the latch 30 will be described with reference to FIG. 9. FIG. 9 is an exploded perspective view showing a state where the notebook case, the latch and the knob are coupled to one another.

The first coupling projection 21 of the knob 20 is inserted into the first coupling groove 35 by passing through the first through-hole 12 of the notebook case 10. The second coupling projection 33 is accommodated in the accommodation space formed by the first coupling projection 21. In this instance, the first coupling projection 21 and the first coupling groove 32 are formed asymmetric, so that it is possible to prevent the knob 20 from being inserted in a wrong direction. Meanwhile, as described above, the second coupling projection 33 may be formed in the direction of the fixing projection 31. This is because, as the first coupling projection 21 of the knob 20 moves, a uniform force is transferred to the first coupling groove 32.

The ribs 22 are inserted into the corresponding rib coupling grooves, respectively. In this instance, the hook 23 formed at the end of each of the ribs 22 is fixed to the stepped portion 25.

Meanwhile, a fixing groove (not shown) corresponding to the fixing projection is formed in the battery case. Since the position and shape of the fixing groove (not shown) is not significantly different from those of the fixing grooves of the related art, a detailed description will be omitted.

### Embodiment 2

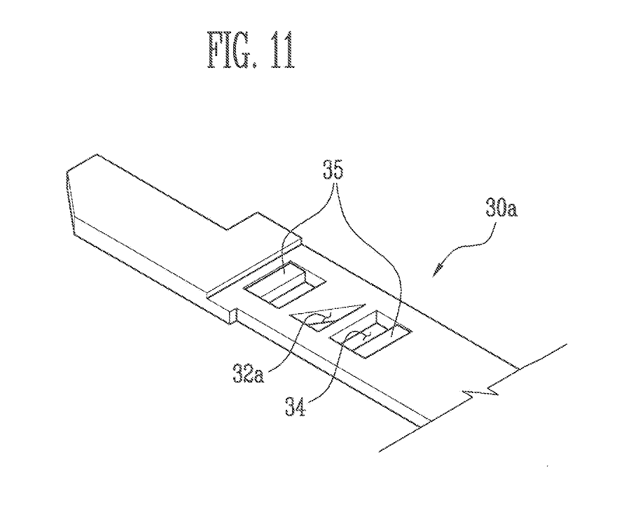

In Embodiment 2, other shapes for the first coupling projection and the first coupling groove will be described with reference to FIGS. 10 and 11. FIG. 10 is a bottom perspective view of a knob 20a according to another embodiment of the present invention. FIG. 11 is a partial perspective view of a latch 30a corresponding to the knob 20a of FIG. 10.

As briefly described above, the first coupling projection and the first coupling groove may be formed asymmetric with the length or width direction of the latch. For the asymmetry, the second coupling projection 33 (see FIG. 7) may be formed as described in the Embodiment 1. However, in this embodiment, the shape of the first coupling groove 32a itself is formed asymmetric. That is, the first coupling groove 32a is formed asymmetric with respect to the length direction and/or width direction of the latch, and a first coupling projection 21a is formed to be inserted with a small gap into the first coupling groove 32a.

In a case where the latch 30a is moved as the knob 20a moves, a constant force is transferred to the first coupling groove 32a. In a case where, the first coupling groove 32a is formed asymmetric with respect to all the length and width directions thereof as described in this embodiment, a uniform force is not transferred to the inner circumferential surface of the first coupling groove 32a. That is, in a case where the first coupling groove 32 is asymmetric with respect to the length direction thereof and symmetric with respect to the width direction thereof as described in the Embodiment of FIG. 9, the first coupling projection 21 transfers a uniform force to the first coupling groove 32.

Meanwhile, the aforementioned locking device may be formed so that the positions of the components respectively formed in the notebook case and the battery case may be exchanged with each other. That is, the latch and knob are formed in the battery case, and the fixing grooves respectively corresponding to the latch and the knob may be formed in the notebook case.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A battery case comprising:
a latch having one end at which a fixing projection is disposed and the other end at which an elastic portion is disposed, the latch having a first coupling groove, wherein the first coupling groove is asymmetric with respect to a length or width direction of the latch:
a first case having first and second through-holes, wherein the fixing projection enters or exits the second through-hole; and
a knob having a first coupling projection, wherein the first coupling projection is inserted into the first coupling groove by passing through the first through-hole.

2. The battery case according to claim 1, wherein the first coupling groove is asymmetric with respect to the length direction of the latch and symmetric with respect to the width direction of the latch.

3. The battery case according to claim 2, wherein a second coupling projection is disposed on an inner circumferential surface of the first coupling groove, and the cross-sectional shape of the first coupling projection accommodates the second coupling projection.

4. The battery case according to claim 3, wherein the second coupling projection is disposed in the direction of the fixing projection of the latch.

5. The battery case according to claim 1, wherein a guide portion that accommodates and guides the latch to move in the length direction of the latch is disposed in the first case.

6. The battery case according to claim 1, wherein rib coupling grooves are disposed at both sides of the first coupling groove of the latch, respectively, and ribs inserted into the rib coupling grooves are disposed at both sides of the first coupling projection of the knob, respectively.

7. The battery case according to claim 6, wherein a hook fixed to each of the rib coupling grooves is disposed at an end of each of the ribs.

8. The battery case according to claim 1, wherein a concave-convex portion is disposed, on the opposite side surface from the first coupling grooves, on the knob.

9. The battery case according to claim 8, wherein the concave-convex portion is biased towards a side with respect to the length direction of the knob.

10. The battery case according to claim 9, wherein the concave-convex portion is biased in the direction of the fixing projection.

11. A notebook case comprising the battery case according to claim 1.

12. A notebook case comprising the battery case according to claim 2.

13. A notebook case comprising the battery case according to claim 3.

14. A notebook case comprising the battery case according to claim 4.

15. A notebook case comprising the battery case according to claim 5.

16. A notebook case comprising the battery case according to claim 6.

17. A notebook case comprising the battery case according to claim 7.

18. A notebook case comprising the battery case according to claim 8.

19. A notebook case comprising the battery case according to claim 9.

20. A notebook case comprising the battery case according to claim 10.
